(19) United States
(12) Patent Application Publication
(10) Pub. No.: US 2023/0336011 A1
(43) Pub. Date: Oct. 19, 2023

(54) AEROSOL-GENERATING DEVICE AND OPERATION METHOD THEREOF

(71) Applicant: KT&G CORPORATION, Daejeon (KR)

(72) Inventors: Daenam HAN, Seoul (KR); Seoksu JANG, Seoul (KR); Seungwon LEE, Gwangmyung-si Gyeonggi-do (KR); Sungwook YOON, Suwon-si Gyeonggi-do (KR); Yonghwan KIM, Anyang-si Gyeonggi-do (KR)

(73) Assignee: KT&G CORPORATION, Daejeon (KR)

(21) Appl. No.: 18/022,960

(22) PCT Filed: Nov. 5, 2021
(86) PCT No.: PCT/KR2021/016009

§ 371 Date: Feb. 23, 2023

(30) Foreign Application Priority Data
Nov. 11, 2020 (KR) 10-2020-0149978

(51) Int. Cl. H02J 7/00; G01R 31/367; G01R 31/374; G01R 31/3842; G01R 19/165; G01R 31/36; A24F 40/50; A24F 40/90; H01M 10/44

(52) U.S. Cl. CPC H02J 7/0048; G01R 31/367; G01R 31/374; G01R 31/3842; G01R 19/16542; G01R 31/3648; A24F 40/50; A24F 40/90; H01M 10/44; H01M 2220/30

(57) ABSTRACT

An aerosol-generating device is disclosed. The aerosol-generating device of the present disclosure includes a heater configured to heat an aerosol-generating substance, a battery configured to supply electric power to the heater, a memory, and a controller configured to determine the remaining capacity of the battery. When the battery is charged, the controller determines whether charging history data on a history of charging the battery to the maximum capacity is stored in the memory. When the charging history data is not stored in the memory, the controller determines the remaining capacity of the battery using an initial data table pertaining to at least one of current or time, which is stored in the memory. When the charging history data is stored in the memory, the controller determines the remaining capacity of the battery based on the charging history data stored in the memory.

### TECHNICAL FIELD

The present disclosure relates to an aerosol-generating device and an operation method thereof.

### BACKGROUND ART

An aerosol-generating device is a device that extracts certain components from a medium or a substance by forming an aerosol. The medium may contain a multi-component substance. The substance contained in the medium may be a multi-component flavoring substance. For example, the substance contained in the medium may include a nicotine component, an herbal component, and/or a coffee component. Recently, various research on aerosol-generating devices has been conducted.

### DISCLOSURE OF INVENTION

### Technical Problem

It is an object of the present disclosure to solve the above and other problems.

It is another object of the present disclosure to provide an aerosol-generating device and an operation method thereof capable of accurately calculating the remaining capacity of a battery based on the presence or absence of a history of charging the battery to the maximum capacity.

### Solution to Problem

An aerosol-generating device according to various embodiments of the present disclosure for accomplishing the above and other objects may include a heater configured to heat an aerosol-generating substance, a battery configured to supply electric power to the heater, a memory, and a controller configured to determine the remaining capacity of the battery. When the battery is charged, the controller may determine whether charging history data on a history of charging the battery to the maximum capacity is stored in the memory. When the charging history data is not stored in the memory, the controller may determine the remaining capacity of the battery using an initial data table pertaining to at least one of current or time, which is stored in the memory. When the charging history data is stored in the memory, the controller may determine the remaining capacity of the battery based on the charging history data stored in the memory.

An operation method of an aerosol-generating device according to various embodiments of the present disclosure for accomplishing the above and other objects may include determining, when the battery of the aerosol-generating device is charged, whether charging history data on a history of charging the battery to the maximum capacity is stored in a memory of the aerosol-generating device, determining, when the charging history data is not stored in the memory, the remaining capacity of the battery using an initial data table pertaining to at least one of current or time, which is stored in the memory, and determining, when the charging history data is stored in the memory, the remaining capacity of the battery based on the charging history data stored in the memory.

### Advantageous Effects of Invention

According to at least one of embodiments of the present disclosure, an initial data table and charging history data are used selectively depending on the presence or absence of a history of charging a battery to the maximum capacity, thereby making it possible to accurately calculate the remaining capacity of the battery.

In addition, according to at least one of embodiments of the present disclosure, charging history data is updated using correction coefficients whenever the battery is charged to the maximum capacity, thereby making it possible to more accurately calculate the remaining capacity of the battery.

Additional applications of the present disclosure will become apparent from the following detailed description. However, because various changes and modifications will be clearly understood by those skilled in the art within the spirit and scope of the present disclosure, it should be understood that the detailed description and specific embodiments, such as preferred embodiments of the present disclosure, are merely given by way of example.

### BRIEF DESCRIPTION OF DRAWINGS

The above and other objects, features and other advantages of the present disclosure will be more clearly understood from the following detailed description taken in conjunction with the accompanying drawings, in which:

FIG. 1 is a block diagram of an aerosol-generating device according to an embodiment of the present disclosure;

FIGS. 2A to 4 are views for explaining an aerosol-generating device according to embodiments of the present disclosure;

FIG. 5 is a flowchart showing an operation method of the aerosol-generating device according to an embodiment of the present disclosure;

FIG. 6 is a flowchart showing an operation method of the aerosol-generating device according to another embodiment of the present disclosure; and

FIGS. 7A to 9 are views for explaining the operation of the aerosol-generating device.

### BEST MODE FOR CARRYING OUT THE INVENTION

Hereinafter, the embodiments disclosed in the present specification will be described in detail with reference to the accompanying drawings. The same or similar elements are denoted by the same reference numerals even though they are depicted in different drawings, and redundant descriptions thereof will be omitted.

In the following description, with respect to constituent elements used in the following description, the suffixes “module” and “unit” are used only in consideration of facilitation of description. The “module” and “unit” are do not have mutually distinguished meanings or functions.

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and sprit of the present disclosure.

It will be understood that the terms “first”, “second”, etc., may be used herein to describe various components. However, these components should not be limited by these terms. These terms are only used to distinguish one component from another component.

It will be understood that when a component is referred to as being “connected to” or “coupled to” another component, it may be directly connected to or coupled to another component. However, it will be understood that intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

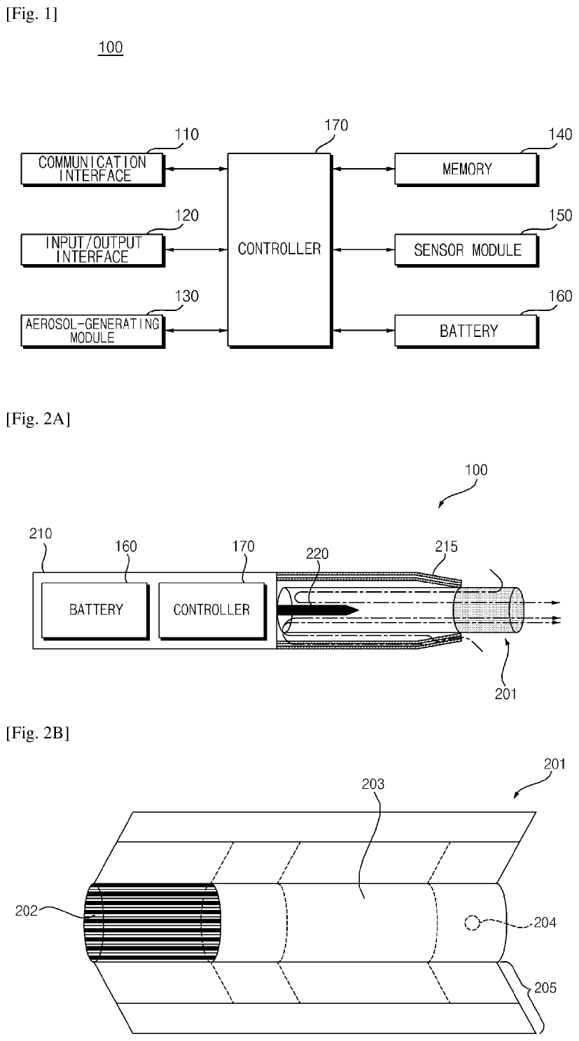

FIG. 1 is a block diagram of an aerosol-generating device according to an embodiment of the present disclosure.

Referring to FIG. 1, an aerosol-generating device 100 may include a communication interface 110, an input/output interface 120, an aerosol-generating module 130, a memory 140, a sensor module 150, a battery 160, and/or a controller 170.

In one embodiment, the aerosol-generating device 100 may be composed only of a main body. In this case, components included in the aerosol-generating device 100 may be located in the main body. In another embodiment, the aerosol-generating device 100 may be composed of a cartridge, which contains an aerosol-generating substance, and a main body. In this case, the components included in the aerosol-generating device 100 may be located in at least one of the main body or the cartridge.

The communication interface 110 may include at least one communication module for communication with an external device and/or a network. For example, the communication interface 110 may include a communication module for wired communication, such as a Universal Serial Bus (USB). For example, the communication interface 110 may include a communication module for wireless communication, such as Wireless Fidelity (Wi-Fi), Bluetooth, Bluetooth Low Energy (BLE), ZigBee, or nearfield communication (NFC).

The input/output interface 120 may include an input device (not shown) for receiving a command from a user and/or an output device (not shown) for outputting information to the user. For example, the input device may include a touch panel, a physical button, a microphone, or the like. For example, the output device may include a display device for outputting visual information, such as a display or a light-emitting diode (LED), an audio device for outputting auditory information, such as a speaker or a buzzer, a motor for outputting tactile information such as haptic effect, or the like.

The input/output interface 120 may transmit data corresponding to a command input by the user through the input device to another component (or other components) of the aerosol-generating device 100. The input/output interface 120 may output information corresponding to data received from another component (or other components) of the aerosol-generating device 100 through the output device.

The aerosol-generating module 130 may generate an aerosol from an aerosol-generating substance. Here, the aerosol-generating substance may be a substance in a liquid state, a solid state, or a gel state, which is capable of generating an aerosol, or a combination of two or more aerosol-generating substances.

According to an embodiment, the liquid aerosol-generating substance may be a liquid including a tobacco-containing material having a volatile tobacco flavor component. According to another embodiment, the liquid aerosol-generating substance may be a liquid including a non-tobacco material. For example, the liquid aerosol-generating substance may include water, solvents, nicotine, plant extracts, flavorings, flavoring agents, vitamin mixtures, etc.

The solid aerosol-generating substance may include a solid material based on a tobacco raw material such as a reconstituted tobacco sheet, shredded tobacco, or granulated tobacco. In addition, the solid aerosol-generating substance may include a solid material having a taste control agent and a flavoring material. For example, the taste control agent may include calcium carbonate, sodium bicarbonate, calcium oxide, etc. For example, the flavoring material may include a natural material such as herbal granules, or may include a material such as silica, zeolite, or dextrin, which includes an aroma ingredient.

In addition, the aerosol-generating substance may further include an aerosol-forming agent such as glycerin or propylene glycol.

The aerosol-generating module 130 may include at least one heater (not shown).

The aerosol-generating module 130 may include an electro-resistive heater. For example, the electro-resistive heater may include at least one electrically conductive track. The electro-resistive heater may be heated as current flows through the electrically conductive track. At this time, the aerosol-generating substance may be heated by the heated electro-resistive heater.

The electrically conductive track may include an electro-resistive material. In one example, the electrically conductive track may be formed of a metal material. In another example, the electrically conductive track may be formed of a ceramic material, carbon, a metal alloy, or a composite of a ceramic material and metal.

The electro-resistive heater may include an electrically conductive track that is formed in any of various shapes. For example, the electrically conductive track may be formed in any one of a tubular shape, a plate shape, a needle shape, a rod shape, and a coil shape.

The aerosol-generating module 130 may include a heater that uses an induction-heating method. For example, the induction heater may include an electrically conductive coil. The induction heater may generate an alternating magnetic field, which periodically changes in direction, by adjusting the current flowing through the electrically conductive coil. At this time, when the alternating magnetic field is applied to a magnetic body, energy loss may occur in the magnetic body due to eddy current loss and hysteresis loss. In addition, the lost energy may be released as thermal energy. Accordingly, the aerosol-generating substance located adjacent to the magnetic body may be heated. Here, an object that generates heat due to the magnetic field may be referred to as a susceptor.

Meanwhile, the aerosol-generating module 130 may generate ultrasonic vibrations to thereby generate an aerosol from the aerosol-generating substance.

The aerosol-generating device 100 may include a plurality of aerosol-generating modules 130. For example, the aerosol-generating device 100 may include a first aerosol-generating module for generating an aerosol by vaporizing a liquid material and a second aerosol-generating module for generating an aerosol by heating a cigarette. A first heater included in the first aerosol-generating module may be a coil heater or a mesh heater. The first aerosol-generating module may be implemented in the form of a cartridge, which is provided separately from the aerosol-generating device 100. The first aerosol-generating module may be referred to as a cartomizer, an atomizer, or a vaporizer. A second heater 134 included in the second aerosol-generating module may be a film heater including an electrically conductive track, or may be a susceptor configured to generate heat using an induction-heating method.

The memory 140 may store programs for processing and controlling each signal in the controller 170, and may store processed data and data to be processed.

For example, the memory 140 may store applications designed for the purpose of performing various tasks that can be processed by the controller 170. The memory 140 may selectively provide some of the stored applications in response to the request from the controller 170.

For example, the memory 140 may store data on the operation time of the aerosol-generating device 100, the maximum number of puffs, the current number of puffs, at least one temperature profile, at least one electric power profile, and the user's inhalation pattern. Here, “puff” means inhalation by the user. “inhalation” means the user's act of taking air or other substances into the user's oral cavity, nasal cavity, or lungs through the user's mouth or nose.

The memory 140 may include at least one of volatile memory (e.g. dynamic random access memory (DRAM), static random access memory (SRAM), or synchronous dynamic random access memory (SDRAM)), nonvolatile memory (e.g. flash memory), a hard disk drive (HDD), or a solid-state drive (SSD).

The sensor module 150 may include at least one sensor.

For example, the sensor module 150 may include a sensor for sensing a puff (hereinafter referred to as a “puff sensor”). In this case, the puff sensor may be implemented by a proximity sensor such as an IR sensor, a pressure sensor, a gyro sensor, an acceleration sensor, a magnetic field sensor, or the like.

For example, the sensor module 150 may include a sensor for sensing the temperature of the heater included in the aerosol-generating module 130 and the temperature of the aerosol-generating substance (hereinafter referred to as a “temperature sensor”). In this case, the heater included in the aerosol-generating module 130 may also serve as the temperature sensor. For example, the electro-resistive material of the heater may be a material having a predetermined temperature coefficient of resistance. The sensor module 150 may measure the resistance of the heater, which varies according to the temperature, to thereby sense the temperature of the heater.

For example, in the case in which the main body of the aerosol-generating device 100 is formed to allow a cigarette to be inserted thereinto, the sensor module 150 may include a sensor for sensing insertion of the cigarette (hereinafter referred to as a “cigarette detection sensor”).

For example, in the case in which the aerosol-generating device 100 includes a cartridge, the sensor module 150 may include a sensor for sensing mounting/demounting of the cartridge and the position of the cartridge (hereinafter referred to as a “cartridge detection sensor”).

In this case, the cigarette detection sensor and/or the cartridge detection sensor may be implemented as an inductance-based sensor, a capacitive sensor, a resistance sensor, or a Hall sensor (or Hall IC) using a Hall effect.

For example, the sensor module 150 may include a voltage sensor for sensing a voltage applied to a component (e.g. the battery 160) provided in the aerosol-generating device 100 and/or a current sensor for sensing a current.

The battery 160 may supply electric power used for the operation of the aerosol-generating device 100 under the control of the controller 170. The battery 160 may supply electric power to other components provided in the aerosol-generating device 100. For example, the battery 160 may supply electric power to the communication module included in the communication interface 110, the output device included in the input/output interface 120, and the heater included in the aerosol-generating module 130.

The battery 160 may be a rechargeable battery or a disposable battery. For example, the battery 160 may be a lithium-ion (Li-ion) battery or a lithium polymer (Li-polymer) battery. However, the present disclosure is not limited thereto. For example, when the battery 160 is rechargeable, the charging rate (C-rate) of the battery 160 may be 10 C, and the discharging rate (C-rate) thereof may be 10 C to 20 C. However, the present disclosure is not limited thereto. Also, for stable use, the battery 160 may be manufactured such that 80% or more of the total capacity may be ensured even when charging/discharging is performed 2000 times.

The aerosol-generating device 100 may further include a battery protection circuit module (PCM) (not shown), which is a circuit for protecting the battery 160. The battery protection circuit module (PCM) may be disposed adjacent to the upper surface of the battery 160. For example, in order to prevent overcharging and overdischarging of the battery 160, the battery protection circuit module (PCM) may cut off the electrical path to the battery 160 when a short circuit occurs in a circuit connected to the battery 160, when an overvoltage is applied to the battery 160, or when an overcurrent flows through the battery 160.

The aerosol-generating device 100 may further include a power terminal (not shown) to which electric power supplied from the outside is input. For example, a power line may be connected to the power terminal, which is disposed at one side of the main body of the aerosol-generating device 100. The aerosol-generating device 100 may use the electric power supplied through the power line connected to the power terminal to charge the battery 160. In this case, the power terminal may be a wired terminal for USB communication.

The aerosol-generating device 100 may wirelessly receive electric power supplied from the outside through the communication interface 110. For example, the aerosol-generating device 100 may wirelessly receive electric power using an antenna included in the communication module for wireless communication. The aerosol-generating device 100 may charge the battery 160 using the wirelessly supplied electric power.

The controller 170 may control the overall operation of the aerosol-generating device 100. The controller 170 may be connected to each of the components provided in the aerosol-generating device 100. The controller 170 may transmit and/or receive a signal to and/or from each of the components, thereby controlling the overall operation of each of the components.

The controller 170 may include at least one processor. The controller 170 may control the overall operation of the aerosol-generating device 100 using the processor included therein. Here, the processor may be a general processor such as a central processing unit (CPU). Of course, the processor may be a dedicated device such as an application-specific integrated circuit (ASIC), or may be any of other hardware-based processors.

The controller 170 may perform any one of a plurality of functions of the aerosol-generating device 100. For example, the controller 170 may perform any one of a plurality of functions of the aerosol-generating device 100 (e.g. a preheating function, a heating function, a charging function, and a cleaning function) according to the state of each of the components provided in the aerosol-generating device 100 and the user's command received through the input/output interface 120.

The controller 170 may control the operation of each of the components provided in the aerosol-generating device 100 based on data stored in the memory 140. For example, the controller 170 may control the supply of a predetermined amount of electric power from the battery 160 to the aerosol-generating module 130 for a predetermined time based on the data on the temperature profile, the electric power profile, and the user's inhalation pattern, which is stored in the memory 140.

The controller 170 may determine the occurrence or non-occurrence of a puff using the puff sensor included in the sensor module 150. For example, the controller 170 may check a temperature change, a flow change, a pressure change, and a voltage change in the aerosol-generating device 100 based on the values sensed by the puff sensor. The controller 170 may determine the occurrence or non-occurrence of a puff based on the value sensed by the puff sensor.

The controller 170 may control the operation of each of the components provided in the aerosol-generating device 100 according to the occurrence or non-occurrence of a puff and/or the number of puffs. For example, upon determining that a puff has occurred, the controller 170 may perform control such that electric power is supplied to the heater according to the electric power profile stored in the memory 140. For example, the controller 170 may perform control such that the temperature of the heater is changed according to the number of puffs based on the temperature profile stored in the memory 140.

The controller 170 may perform control such that the supply of electric power to the heater is interrupted according to a predetermined condition. For example, the controller 170 may perform control such that the supply of electric power to the heater is interrupted when the cigarette is removed, when the cartridge is demounted, when the number of puffs reaches the predetermined maximum number of puffs, when a puff is not sensed during a predetermined period of time or longer, or when the remaining capacity of the battery 160 is less than a predetermined value.

The controller 170 may calculate the remaining capacity with respect to the full charge capacity of the battery 160. For example, the controller 170 may calculate the remaining capacity of the battery 160 based on the values sensed by the voltage sensor and/or the current sensor included in the sensor module 150.

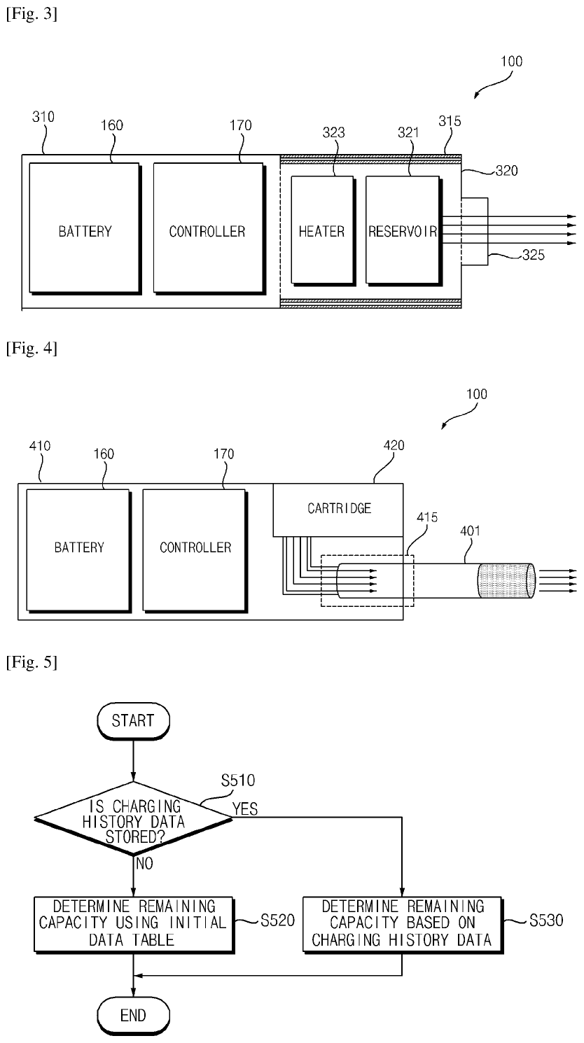

FIGS. 2A to 4 are views for explaining the aerosol-generating device according to embodiments of the present disclosure.

According to various embodiments of the present disclosure, the aerosol-generating device 100 may include a main body and/or a cartridge.

Referring to FIG. 2A, the aerosol-generating device 100 according to an embodiment may include a main body 210, which is formed such that a cigarette 201 can be inserted into the inner space formed by a housing 215.

The cigarette 201 may be similar to a general combustive cigarette. For example, the cigarette 201 may be divided into a first portion including an aerosol-generating substance and a second portion including a filter. Alternatively, the second portion of the cigarette 201 may also include an aerosol-generating substance. For example, a granular or capsular flavoring material may be inserted into the second portion.

The entirety of the first portion may be inserted into the aerosol-generating device 100. The second portion may be exposed to the outside. Alternatively, only a portion of the first portion may be inserted into the aerosol-generating device 100. Alternatively, the entirety of the first portion and a portion of the second portion may be inserted into the aerosol-generating device 100. The user may inhale the aerosol in the state of holding the second portion in the mouth. At this time, the aerosol may be generated as external air passes through the first portion. The generated aerosol may pass through the second portion to be introduced into the mouth of the user.

The main body 210 may be structured such that external air is introduced into the main body 210 in the state in which the cigarette 201 is inserted thereinto. In this case, the external air introduced into the main body 210 may flow into the mouth of the user via the cigarette 201.

When the cigarette 201 is inserted, the controller 170 may perform control such that electric power is supplied to the heater based on the temperature profile stored in the memory 140.

The heater may be disposed in the main body 210 at a position corresponding to the position at which the cigarette 201 is inserted into the main body 210. Although it is illustrated in the drawings that the heater is an electrically conductive heater 220 including a needle-shaped electrically conductive track, the present disclosure is not limited thereto.

The heater may heat the interior and/or exterior of the cigarette 201 using the electric power supplied from the battery 160. An aerosol may be generated from the heated cigarette 201. At this time, the user may hold one end of the cigarette 201 in the mouth to inhale the aerosol containing a tobacco material.

Meanwhile, the controller 170 may perform control such that electric power is supplied to the heater in the state in which the cigarette 201 is not inserted into the main body according to a predetermined condition. For example, when a cleaning function for cleaning the space into which the cigarette 201 is inserted is selected in response to a command input by the user through the input/output interface 120, the controller 170 may perform control such that a predetermined amount of electric power is supplied to the heater.

The controller 170 may monitor the number of puffs based on the value sensed by the puff sensor from the time point at which the cigarette 201 was inserted into the main body.

When the cigarette 201 is removed from the main body, the controller 170 may initialize the current number of puffs stored in the memory 140.

Referring to FIG. 2B, the cigarette 201 according to an embodiment may include a tobacco rod 202 and a filter rod 203. The first portion described above with reference to FIG. 2A may include the tobacco rod 202. The second portion described above with reference to FIG. 2A may include the filter rod 203.

Although it is illustrated in FIG. 2B that the filter rod 203 is composed of a single segment, the present disclosure is not limited thereto. In other words, the filter rod 203 may be composed of a plurality of segments. For example, the filter rod 203 may include a first segment configured to cool an aerosol and a second segment configured to remove a predetermined component included in the aerosol. In addition, the filter rod 203 may further include at least one segment configured to perform other functions, as needed.

The cigarette 201 may be packed using at least one wrapper 205. The wrapper 205 may have at least one hole formed therein to allow external air to be introduced thereinto or to allow internal gas to be discharged therefrom. In one example, the cigarette 201 may be packed using one wrapper 205. In another example, the cigarette 201 may be doubly packed using two or more wrappers 205. For example, the tobacco rod 202 may be packed using a first wrapper. For example, the filter rod 203 may be packed using a second wrapper. The tobacco rod 202 and the filter rod 203, which are individually packed using separate wrappers, may be coupled to each other. The entire cigarette 201 may be packed using a third wrapper. When each of the tobacco rod 202 and the filter rod 203 is composed of a plurality of segments, each segment may be packed using a separate wrapper. The entire cigarette 201, formed by coupling segments, each of which is packed using a separate wrapper, to each other, may be packed using another wrapper.

The tobacco rod 202 may include an aerosol-generating substance. For example, the aerosol-generating substance may include at least one of glycerin, propylene glycol, ethylene glycol, dipropylene glycol, diethylene glycol, triethylene glycol, tetraethylene glycol, or oleyl alcohol, but the present disclosure is not limited thereto. Also, the tobacco rod 202 may include other additives, such as a flavoring agent, a wetting agent, and/or an organic acid. Also, a flavoring liquid, such as menthol or a moisturizer, may be injected into and added to the tobacco rod 202.

The tobacco rod 202 may be manufactured in various forms. For example, the tobacco rod 202 may be formed as a sheet or a strand. For example, the tobacco rod 202 may be formed as shredded tobacco, which is formed by cutting a tobacco sheet into tiny bits. For example, the tobacco rod 202 may be surrounded by a thermally conductive material. For example, the thermally conductive material may be a metal foil such as aluminum foil, but the present disclosure is not limited thereto. In one example, the thermally conductive material surrounding the tobacco rod 202 may uniformly distribute heat transmitted to the tobacco rod 202, thereby improving conduction of the heat applied to the tobacco rod. This may improve the taste of the tobacco. The thermally conductive material surrounding the tobacco rod 202 may function as a susceptor that is heated by the induction heater. Here, although not illustrated in the drawings, the tobacco rod 202 may further include an additional susceptor, in addition to the thermally conductive material surrounding the tobacco rod 202.

The filter rod 203 may be a cellulose acetate filter. The filter rod 203 may be formed in any of various shapes. For example, the filter rod 203 may be a cylinder-type rod. For example, the filter rod 203 may be a hollow tube-type rod. For example, the filter rod 203 may be a recess-type rod. When the filter rod 203 is composed of a plurality of segments, at least one of the plurality of segments may be formed in a different shape.

The filter rod 203 may be formed to generate flavors. In one example, a flavoring liquid may be injected into the filter rod 203. In one example, a separate fiber coated with a flavoring liquid may be inserted into the filter rod 203.

In addition, the filter rod 203 may include at least one capsule 204. Here, the capsule 204 may function to generate a flavor. The capsule 204 may function to generate an aerosol. For example, the capsule 204 may have a structure in which a liquid containing a flavoring material is wrapped with a film. The capsule 204 may have a spherical or cylindrical shape, but the present disclosure is not limited thereto.

When the filter rod 203 includes a segment configured to cool the aerosol, the cooling segment may be made of a polymer material or a biodegradable polymer material. For example, the cooling segment may be made of pure polylactic acid alone, but the present disclosure is not limited thereto. Alternatively, the cooling segment may be formed as a cellulose acetate filter having a plurality of holes formed therein. However, the cooling segment is not limited to the above-described example, and any other type of cooling segment may be used, so long as the same is capable of cooling the aerosol.

Although not illustrated in FIG. 2B, the cigarette 201 according to an embodiment may further include a front-end filter. The front-end filter may be located at the side of the tobacco rod 202 that faces the filter rod 203. The front-end filter may prevent the tobacco rod 202 from becoming detached outwards. The front-end filter may prevent a liquefied aerosol from flowing into the aerosol-generating device 100 from the tobacco rod 202 during inhalation by the user.

Referring to FIG. 3, the aerosol-generating device 100 according to an embodiment may include a main body 310 and a cartridge 320. The main body 310 may support the cartridge 320, and the cartridge 320 may contain an aerosol-generating substance.

According to one embodiment, the cartridge 320 may be configured so as to be detachably mounted to the main body 310. According to another embodiment, the cartridge 320 may be formed integrally with the main body 310. For example, the cartridge 320 may be mounted to the main body 310 in a manner such that at least a portion of the cartridge 320 is inserted into the inner space formed by a housing 315 of the main body 310.

The main body 310 may be formed to have a structure in which external air can be introduced into the main body 310 in the state in which the cartridge 320 is inserted thereinto. Here, the external air introduced into the main body 310 may flow into the user's mouth via the cartridge 320.

The controller 170 may determine whether the cartridge 320 is in a mounted state or a detached state using a cartridge detection sensor included in the sensor module 150. For example, the cartridge detection sensor may transmit a pulse current through a terminal connected to the cartridge 320. In this case, the cartridge detection sensor may determine whether the cartridge 320 is in a connected state, based on whether the pulse current is received through another terminal.

The cartridge 320 may include a reservoir 321 configured to contain the aerosol- generating substance and/or a heater 323 configured to heat the aerosol-generating substance in the reservoir 321. For example, a liquid delivery element impregnated with (containing) the aerosol-generating substance may be disposed inside the reservoir 321. The electrically conductive track of the heater 323 may be formed in a structure that is wound around the liquid delivery element. In this case, when the liquid delivery element is heated by the heater 323, an aerosol may be generated. Here, the liquid delivery element may include a wick made of, for example, cotton fiber, ceramic fiber, glass fiber, or porous ceramic.

The cartridge 320 may include a mouthpiece 325. Here, the mouthpiece 325 may be a portion to be inserted into a user's oral cavity. The mouthpiece 325 may have a discharge hole through which the aerosol is discharged to the outside during a puff.

Referring to FIG. 4, the aerosol-generating device 100 according to an embodiment may include a main body 410 supporting the cartridge 420 and a cartridge 420 containing an aerosol-generating substance. The main body 410 may be formed so as to allow a cigarette 401 to be inserted into an inner space 415 therein.

The aerosol-generating device 100 may include a first heater for heating the aerosol-generating substance stored in the cartridge 420. For example, when the user holds one end of the cigarette 401 in the mouth to inhale the aerosol, the aerosol generated by the first heater may pass through the cigarette 401. At this time, while the aerosol passes through the cigarette 401, a tobacco material may be added to the aerosol. The aerosol containing the tobacco material may be drawn into the user's oral cavity through one end of the cigarette 401.

Alternatively, according to another embodiment, the aerosol-generating device 100 may include a first heater for heating the aerosol-generating substance stored in the cartridge 420 and a second heater for heating the cigarette 401 inserted into the main body 410. For example, the aerosol-generating device 100 may generate an aerosol by heating the aerosol-generating substance stored in the cartridge 420 and the cigarette 401 using the first heater and the second heater, respectively.

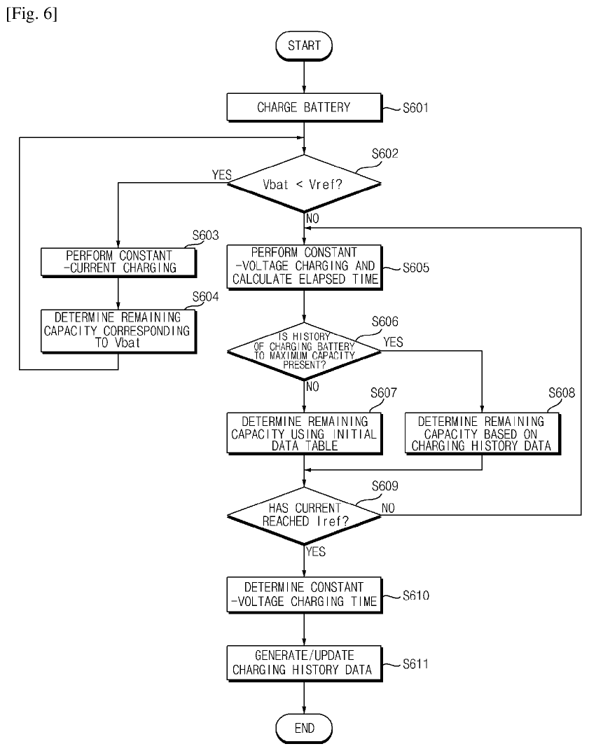

FIG. 5 is a flowchart showing an operation method of the aerosol-generating device according to an embodiment of the present disclosure.

Referring to FIG. 5, the aerosol-generating device 100 may determine, when the battery 160 is charged, whether data on a history of charging the battery 160 to the maximum capacity (hereinafter referred to as “charging history data”) is stored in the memory 140 in operation S510. Here, the charging history data may include a time period from a time point at which the voltage Vbat of the battery 160 reached a predetermined voltage level Vref to a time point at which the current flowing through the battery 160 reached a second current level Tref (hereinafter referred to as a “constant-voltage charging time”), and the level of current flowing through the battery 160, sensed during the constant-voltage charging time period.

When the charging history data is not stored in the memory 140, the aerosol-generating device 100 may determine the remaining capacity of the battery 160 using an initial data table pertaining to at least one of current or time, which is stored in the memory 160, in operation S520. Here, the initial data table may be a data table stored in the aerosol-generating device 100 before being shipped from the factory. The initial data table may be a data table including data on a plurality of remaining capacities mapped to respective ones of a plurality of elapsed times. In this regard, an example of the initial data table will be described with reference to Table 1 below.

TABLE 1

| Voltage [V] | Current [A] | Time [sec] | Remaining Capacity [%] |
|---|---|---|---|
| 4.4 | 2 | 0 | 80 |
| 4.4 | 1.6 | 50 | 82 |
| 4.4 | 1.3 | 135 | 84 |
| 4.4 | 1 | 240 | 87 |
| 4.4 | 0.7 | 360 | 90 |
| 4.4 | 0.5 | 480 | 93 |
| 4.4 | 0.3 | 720 | 100 |

For example, as shown in Table 1, when the predetermined voltage level Vref is set to 4.4V, when the first current level Icc is set to 2 A, and when the second current level Iref is set to 0.3 A, the aerosol-generating device 100 may monitor the elapsed time from when the voltage of the battery 160 reaches 4.4V to when the current flowing through the battery 160 reaches 0.3 A.

In this case, the aerosol-generating device 100 may determine the remaining capacity corresponding to the elapsed time, among the plurality of remaining capacities included in the initial data table, to be the remaining capacity of the battery 160. For example, when the elapsed time is 240 seconds, the aerosol-generating device 100 may determine the remaining capacity of the battery 160 to be 87% using Table 1. When the elapsed time is 480 seconds, the aerosol-generating device 100 may determine the remaining capacity of the battery 160 to be 93%.

On the other hand, when the charging history data is stored in the memory 140, the aerosol-generating device 100 may determine the remaining capacity of the battery 160 based on the charging history data stored in the memory 140 in operation S530.

The aerosol-generating device 100 may determine the charging capacity of the battery 160 corresponding to the elapsed time by calculating the ratio of the elapsed time to the constant-voltage charging time included in the charging history data. For example, when the remaining capacity of the battery 160 corresponding to the predetermined voltage level Vref is 80%, the charging capacity of the battery 160 corresponding to the constant-voltage charging time may be 20%. In this case, when the constant-voltage charging time included in the charging history data is 900 seconds and when the calculated elapsed time is 400 seconds, the aerosol-generating device 100 may calculate the ratio of the elapsed time to the constant-voltage charging time to be 0.5. In addition, the aerosol-generating device 100 may determine the charging capacity of the battery 160 corresponding to the elapsed time to be 10%.

Also, the aerosol-generating device 100 may determine the remaining capacity of the battery 160 by adding the charging capacity of the battery 160 corresponding to the elapsed time to the remaining capacity of the battery 160 corresponding to the predetermined voltage level Vref. For example, when the remaining capacity of the battery 160 corresponding to the predetermined voltage level Vref is calculated to be 80% and when the charging capacity of the battery 160 corresponding to the elapsed time is calculated to be 10%, the aerosol-generating device 100 may determine the remaining capacity of the battery 160 to be 90%.

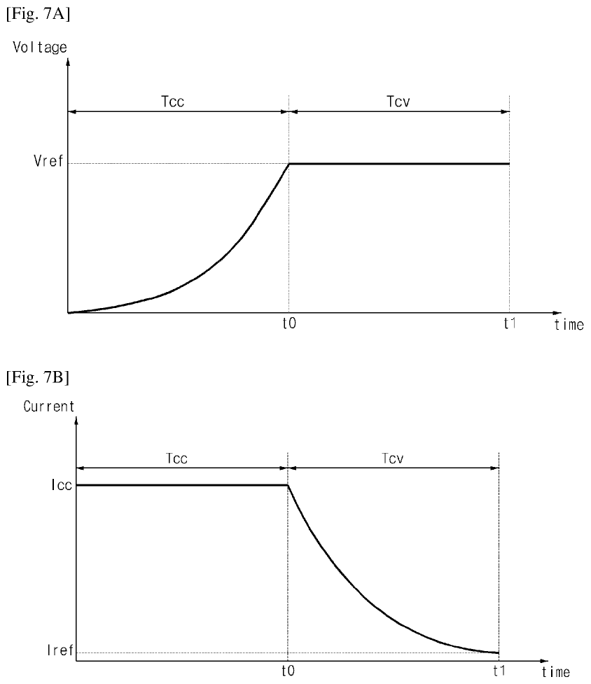

FIG. 6 is a flowchart showing an operation method of the aerosol-generating device according to another embodiment of the present disclosure.

Referring to FIG. 6, the aerosol-generating device 100 may charge the battery 160 in operation S601. For example, in the case in which a power cable is connected to a power terminal (e.g. a wired terminal for USB communication) disposed at a portion of the main body of the aerosol-generating device 100, the aerosol-generating device 100 may charge the battery 160 using electric power supplied through the power cable.

The aerosol-generating device 100 may check the voltage Vbat of the battery 160 in operation S602. The aerosol-generating device 100 may determine whether the voltage Vbat of the battery 160 is less than the predetermined voltage level Vref. For example, the aerosol-generating device 100 may monitor the voltage Vbat of the battery 160 by sensing the voltage applied to the battery 160 using a voltage sensor included in the sensor module 150 while charging the battery 160.

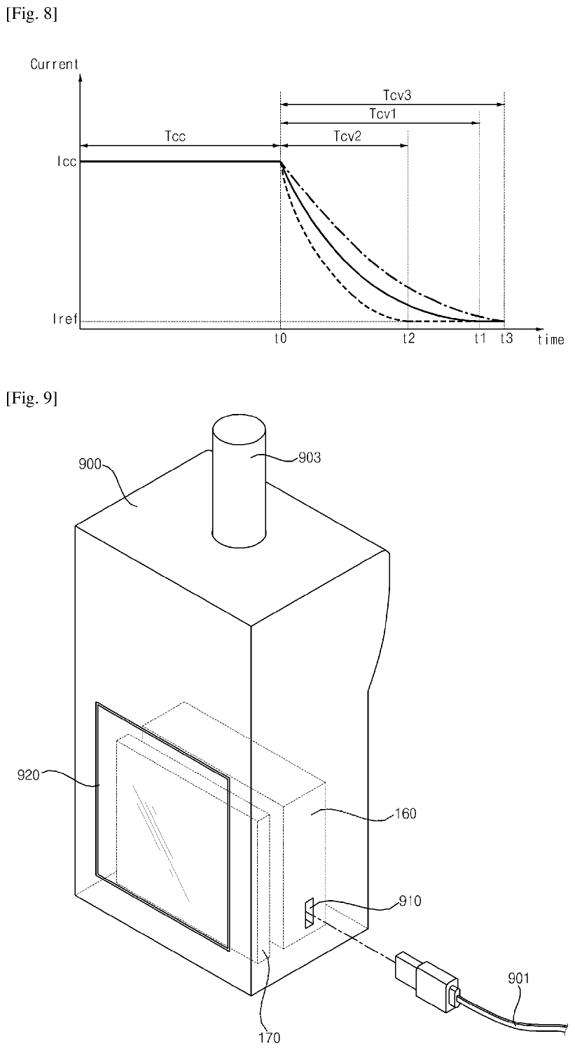

Here, the predetermined voltage level Vref may be a voltage level preset to distinguish the charging stage of the battery 160. In this regard, FIGS. 6A and 6B will be described with reference to FIGS. 7A and 7B.

FIG. 7A is an example of a graph indicating the voltage of the battery 160, sensed while charging the battery 160, and FIG. 7B is an example of a graph indicating the current flowing through the battery 160, sensed while charging the battery 160.

Referring to FIGS. 7A and 7B, the aerosol-generating device 100 may maintain the current flowing through the battery 160 at the preset first current level Icc in the section Tcc in which the voltage Vbat of the battery 160 is less than the predetermined voltage level Vref. In this case, the voltage Vbat of the battery 160 may gradually increase.

Here, the section Tcc in which the current flowing through the battery 160 is maintained at the first current level Icc may be referred to as a “constant-current charging section”

Meanwhile, when the voltage Vbat of the battery 160 reaches the predetermined voltage level Vref, the aerosol-generating device 100 may maintain the voltage Vbat of the battery 160 at the predetermined voltage level Vref. In this case, the current flowing through the battery 160 may gradually decrease. The remaining capacity of the battery 160 may increase to the maximum capacity while the voltage Vbat of the battery 160 is maintained at the predetermined voltage level Vref.

Here, the section Tcv in which the voltage Vbat of the battery 160 is maintained at the predetermined voltage level Vref may be referred to as a “constant-voltage charging section”

When the current flowing through the battery 160 reaches the second current level Iref, which is lower than the first current level Icc, in the constant-voltage charging section Tcv, the aerosol-generating device 100 may determine that the remaining capacity of the battery 160 has reached the maximum capacity.

In most cases, the aerosol-generating device 100 is shipped from the factory in the state in which the battery 160 is not charged to the maximum capacity for reasons such as prevention of explosion of the battery 160. Therefore, until the battery 160 is charged to the maximum capacity after shipment from the factory, the aerosol-generating device 100 has difficulty accurately determining the second time point t1 at which the current flowing through the battery 160 reaches the second current level Iref and variation in the current flowing through the battery 160 in the second section Tcv.

In the second section Tcv, the voltage Vbat of the battery 160 is maintained at the predetermined voltage level Vref. However, the remaining capacity of the battery 160 varies over time up to the maximum capacity. Therefore, there is a need for a method whereby the aerosol-generating device 100 is capable of accurately calculating the remaining capacity of the battery 160 in the second section Tcv.

Referring again to FIG. 6, when the voltage Vbat of the battery 160 is less than the predetermined voltage level Vref, the aerosol-generating device 100 may perform constant-current charging to maintain the current flowing through the battery 160 at the preset first current level Icc in operation 5603.

The aerosol-generating device 100 may determine the remaining capacity of the battery 160 in consideration of the voltage Vbat of the battery 160 in operation S604.

The aerosol-generating device 100 may determine the remaining capacity of the battery 160 based on the ratio of the voltage Vbat of the battery 160 to the predetermined voltage level Vref. For example, when the predetermined voltage level Vref is 4.4V and when the voltage Vbat of the battery 160 is 3.3V, the ratio of the voltage Vbat of the battery 160 to the predetermined voltage level Vref may be calculated to be 0.75. The aerosol-generating device 100 may determine 60%, which is a value obtained by multiplying the calculated ratio by the remaining capacity (e.g. 80%) corresponding to the predetermined voltage level Vref, to be the remaining capacity of the battery 160.

In addition, the aerosol-generating device 100 may output information on the remaining capacity of the battery 160 through an output device (e.g. a display) included in the input/output interface 120.

When the voltage Vbat of the battery 160 reaches the predetermined voltage level Vref, the aerosol-generating device 100 may perform constant-voltage charging to maintain the voltage Vbat of the battery 160 at the predetermined voltage level Vref in operation S605. In this case, the aerosol-generating device 100 may calculate the amount of time that has elapsed since the voltage Vbat of the battery 160 reached the predetermined voltage level Vref (hereinafter referred to as the “elapsed time”).

The aerosol-generating device 100 may determine whether the charging history data is stored in the memory 140 in operation S606.

When charging history data is not stored in the memory 140, the aerosol-generating device 100 may determine the remaining capacity of the battery 160 using the initial data table pertaining to at least one of current or time, which is stored in the memory 160, in operation S607.

In this case, the aerosol-generating device 100 may determine the remaining capacity corresponding to the elapsed time, among the plurality of remaining capacities included in the initial data table, to be the remaining capacity of the battery 160. For example, when the elapsed time is 240 seconds, the aerosol-generating device 100 may determine the remaining capacity of the battery 160 to be 87% using Table 1. When the elapsed time is 480 seconds, the aerosol-generating device 100 may determine the remaining capacity of the battery 160 to be 93%.

On the other hand, when the charging history data is stored in the memory 140, the aerosol-generating device 100 may determine the remaining capacity of the battery 160 based on the charging history data stored in the memory 140 in operation 5608.

The aerosol-generating device 100 may determine the charging capacity of the battery 160 corresponding to the elapsed time by calculating the ratio of the elapsed time to the constant-voltage charging time included in the charging history data. Also, the aerosol-generating device 100 may determine the remaining capacity of the battery 160 by adding the charging capacity of the battery 160 corresponding to the elapsed time to the remaining capacity of the battery 160 corresponding to the predetermined voltage level Vref.

The aerosol-generating device 100 may determine whether the current flowing through the battery 160 reaches the second current level Tref in operation S609.

When the current flowing through the battery 160 has not reached the second current level Iref, the aerosol-generating device 100 may continuously perform the constant-voltage charging. That is, when the remaining capacity of the battery 160 has not reached the maximum capacity, the aerosol-generating device 100 may continuously perform constant-voltage charging.

On the other hand, when the current flowing through the battery 160 has reached the second current level Iref, the aerosol-generating device 100 may determine the constant-voltage charging time in operation S610. That is, the aerosol-generating device 100 may determine the time period from the time point at which the voltage Vbat of the battery 160 reaches the predetermined voltage level Vref to the time point at which the current flowing through the battery 160 reaches the second current level Iref.

In addition, when the current flowing through the battery 160 reaches the second current level Iref, the aerosol-generating device 100 may output a message indicating a fully charged state through the output device included in the input/output interface 120. The user may recognize the fully charged state of the battery 160 through the message indicating the fully charged state. For example, when the current flowing through the battery 160 reaches the second current level Iref, the aerosol-generating device 100 may generate a vibration indicating the fully charged state using a motor for outputting tactile information such as a haptic effect.

The aerosol-generating device 100 may generate or update the charging history data in operation S611.

When the charging history data is not stored in the memory 140, the aerosol-generating device 100 may generate charging history data. That is, when the battery 160 is initially charged to the maximum capacity after being shipped from the factory, the aerosol-generating device 100 may generate charging history data including the constant-voltage charging time determined in operation S610.

When the charging history data is stored in the memory 140, the aerosol-generating device 100 may update the charging history data stored in the memory 140 based on the constant-voltage charging time determined in operation S610.

Referring to FIG. 8, when the battery 160 is charged, the time point at which the current flowing through the battery 160 reaches the second current level Iref may be changed to t1, t2, or t3 depending on various conditions such as the state of the battery 160, the body temperature of the user, or the outdoor temperature. The constant-voltage charging section may also be charged to Tcv1, Tcv2, or Tcv3. Therefore, in order to more accurately calculate the remaining capacity of the battery 160, the aerosol-generating device 100 may update the charging history data stored in the memory 140 whenever the battery 160 is fully charged.

For example, the aerosol-generating device 100 may compare the constant-voltage charging time determined in operation S610 (hereinafter referred to as a “first charging time T1”) with the constant-voltage charging time included in the charging history data stored in the memory 140 (hereinafter referred to as a “second charging time T2”).

In this case, when the first charging time T1 and the second charging time T2 are different from each other, for example, when the difference between the first charging time T1 and the second charging time T2 exceeds a predetermined difference, the charging history data may be updated using correction coefficients. This will be described with reference to Equation 1 below, which is an example of using the correction coefficients.

T3=a×T1+b×T2,a+b=1

For example, the aerosol-generating device 100 may calculate the sum of a value obtained by multiplying the first charging time T1 by a first correction coefficient a and a value obtained by multiplying the second charging time T2 by a second correction coefficient b as the third charging time T3. In this case, the sum of the first correction coefficient a and the second correction coefficient b may be 1.

That is, an error may occur in the calculation of the constant-voltage charging time depending on the state of the battery 160 during charging. In consideration thereof, the aerosol-generating device 100 may use both the constant-voltage charging time determined in the most recent charging operation and the constant-voltage charging time calculated in the corresponding charging operation, with the correction coefficients applied thereto, thereby more accurately determining the constant-voltage charging time, which is updated in the charging history data.

Also, in consideration of the fact that the constant-voltage charging time calculated in the corresponding charging operation more closely matches the current state of the battery 160, the second correction coefficient b may be smaller than the first correction coefficient a.

FIG. 9 is a perspective view schematically showing an example of the aerosol-generating device 100 to which the present disclosure is applied.

Referring to FIG. 9, when a power cable 901 is connected to a power terminal 910 (e.g. a wired terminal for USB communication), which is disposed at one side of a main body 900, the controller 170 of the aerosol-generating device 100 may start a function of charging the battery 160 in response to a signal generated by connection of the power terminal 910 and the power cable 901.

When the power cable 901 is connected to the power terminal 910 in the state in which a cigarette 903 is inserted into the main body 900, the controller 170 may interrupt the supply of electric power to the aerosol-generating module 130. The controller 170 may perform control such that the battery 160 is charged when the power cable 901 is connected to the power terminal 910.

The controller 170 may output an image indicating the remaining capacity of the battery 160 through a display 920, which is disposed at another side of the main body 900. When the charging history data is not stored in the memory 140, the controller 170 may output an image indicating a request for full charging as well as an image indicating the remaining capacity of the battery 160 through the display 920. That is, until the battery 160 is charged to the maximum capacity after shipment from the factory, the controller 170 may output an image indicating a request for full charging as well as an image indicating the remaining capacity of the battery 160 through the display 920.

As described above, according to at least one of the embodiments of the present disclosure, the initial data table and the charging history data are used selectively depending on the presence or absence of a history of charging the battery 160 to the maximum capacity, thereby making it possible to accurately calculate the remaining capacity of the battery 160.

In addition, according to at least one of the embodiments of the present disclosure, the charging history data is updated using correction coefficients whenever the battery 160 is charged to the maximum capacity, thereby making it possible to more accurately calculate the remaining capacity of the battery 160.

Referring to FIGS. 1 to 9, an aerosol-generating device 100 according to an embodiment of the present disclosure may include a heater configured to heat an aerosol-generating substance, a memory 140, a battery 160 configured to supply electric power to the heater, and a controller 170 configured to determine the remaining capacity of the battery 160. When the battery 160 is charged, the controller 170 may determine whether charging history data on a history of charging the battery 160 to the maximum capacity is stored in the memory 140. When the charging history data is not stored in the memory 140, the controller 170 may determine the remaining capacity of the battery 160 using an initial data table pertaining to at least one of current or time, which is stored in the memory 140. When the charging history data is stored in the memory 140, the controller 170 may determine the remaining capacity of the battery 160 based on the charging history data stored in the memory 140.

In addition, in the aerosol-generating device 100 according to an embodiment of the present disclosure, when the voltage of the battery 160 is less than a predetermined voltage level, the controller 170 may determine the remaining capacity of the battery corresponding to the voltage of the battery. When the voltage of the battery 160 is equal to or greater than the predetermined voltage level, the controller 170 may determine whether the charging history data is stored in the memory 140.

In addition, in the aerosol-generating device 100 according to an embodiment of the present disclosure, when the voltage of the battery 160 is less than the predetermined voltage level, the controller 170 may perform control such that the current flowing through the battery 160 is maintained at a first current level. When the voltage of the battery 160 is equal to or greater than the predetermined voltage level, the controller 170 may perform control such that the voltage of the battery 160 is maintained at the predetermined voltage level. The controller 170 may calculate a time period from when the voltage of the battery 160 becomes equal to or greater than the predetermined voltage level to when the current flowing through the battery becomes equal to or less than a second current level, which is lower than the first current level. When the current flowing through the battery 160 is equal to or less than the second current level and when the charging history data is not stored in the memory 140, the controller 170 may generate charging history data, including the calculated time period as a constant-voltage charging time, and may store the generated charging history data in the memory 140.

In addition, the initial data table according to an embodiment of the present disclosure may include data on a plurality of remaining capacities mapped to respective ones of a plurality of elapsed times. When the charging history data is not stored in the memory, the controller may determine a remaining capacity corresponding to a time elapsed since the voltage of the battery 160 reaches the predetermined voltage level, among the plurality of remaining capacities included in the initial data table, to be the remaining capacity of the battery 160.

In addition, the charging history data according to an embodiment of the present disclosure may include a time period from when the voltage of the battery 160 becomes equal to or greater than the predetermined voltage level to when the battery 160 is charged to the maximum capacity. When the charging history data is stored in the memory 140, the controller 170 of the aerosol-generating device 100 may calculate the ratio of a time elapsed since the voltage of the battery reaches the predetermined voltage level to a time included in the charging history data, and may determine the remaining capacity of the battery 160 by adding an additional capacity corresponding to the ratio to a remaining capacity corresponding to the predetermined voltage level.

In addition, when the current flowing through the battery 160 is equal to or less than the second current level and when the charging history data is stored in the memory 140, the controller 170 of the aerosol-generating device 100 according to an embodiment of the present disclosure may compare the calculated time period with the constant-voltage charging time included in the charging history data. When the calculated time period and the constant-voltage charging time are different from each other, the controller 170 may calculate the sum of a value obtained by multiplying the calculated time period by a first correction coefficient and a value obtained by multiplying the constant-voltage charging time by a second correction coefficient as a final charging time. The controller 170 may update the constant-voltage charging time included in the charging history data with the calculated final charging time.

In addition, an operation method of the aerosol-generating device 100 according to an embodiment of the present disclosure may include determining, when the battery 160 of the aerosol-generating device 100 is charged, whether charging history data on a history of charging the battery 160 to the maximum capacity is stored in the memory 140 of the aerosol-generating device 100, determining, when the charging history data is not stored in the memory 140, the remaining capacity of the battery 160 using an initial data table pertaining to at least one of current or time, which is stored in the memory 140, and determining, when the charging history data is stored in the memory 140, the remaining capacity of the battery 160 based on the charging history data stored in the memory 140.

In addition, the operation method of the aerosol-generating device 100 according to an embodiment of the present disclosure may further include determining, when the voltage of the battery 160 is less than a predetermined voltage level, the remaining capacity of the battery 160 corresponding to the voltage of the battery 160. The determining whether the charging history data is stored in the memory 140 of the aerosol-generating device 100 may be performed when the voltage of the battery 160 is equal to or greater than the predetermined voltage level.

In addition, the operation method of the aerosol-generating device 100 according to an embodiment of the present disclosure may further include maintaining, when the voltage of the battery 160 is less than the predetermined voltage level, the current flowing through the battery 160 at a first current level, maintaining, when the voltage of the battery 160 is equal to or greater than the predetermined voltage level, the voltage of the battery 160 at the predetermined voltage level, calculating a time period from when the voltage of the battery 160 becomes equal to or greater than the predetermined voltage level to when the current flowing through the battery 160 becomes equal to or less than a second current level, which is lower than the first current level, generating, when the current flowing through the battery 160 is equal to or less than the second current level and when the charging history data is not stored in the memory 140, charging history data, including the calculated time period as a constant-voltage charging time, and storing the generated charging history data in the memory 140.

In addition, the initial data table according to an embodiment of the present disclosure may include data on a plurality of remaining capacities mapped to respective ones of a plurality of elapsed times. In the operation method of the aerosol-generating device 100, the determining the remaining capacity of the battery 160 using the initial data table may include determining a remaining capacity corresponding to a time elapsed since the voltage of the battery reaches the predetermined voltage level, among the plurality of remaining capacities included in the initial data table, to be the remaining capacity of the battery 160.

In addition, the charging history data according to an embodiment of the present disclosure may include a time period from when the voltage of the battery 160 becomes equal to or greater than the predetermined voltage level to when the battery 160 is charged to the maximum capacity. In the operation method of the aerosol-generating device 100, the determining the remaining capacity of the battery 160 based on the charging history data may include calculating the ratio of a time elapsed since the voltage of the battery 160 reaches the predetermined voltage level to a time included in the charging history data and determining the remaining capacity of the battery 160 by adding an additional capacity corresponding to the ratio to a remaining capacity corresponding to the predetermined voltage level.

In addition, the operation method of the aerosol-generating device 100 according to an embodiment of the present disclosure may further include comparing, when the current flowing through the battery 160 is equal to or less than the second current level and when the charging history data is stored in the memory 140, the calculated time period with the constant-voltage charging time included in the charging history data, calculating, when the calculated time period and the constant-voltage charging time are different from each other, the sum of a value obtained by multiplying the calculated time period by a first correction coefficient and a value obtained by multiplying the constant-voltage charging time by a second correction coefficient as a final charging time, and updating the constant-voltage charging time included in the charging history data with the calculated final charging time.

In addition, in the operation method of the aerosol-generating device 100 according to an embodiment of the present disclosure, the sum of the first correction coefficient and the second correction coefficient may be 1, and the second correction coefficient may be smaller than the first correction coefficient.

Certain embodiments or other embodiments of the disclosure described above are not mutually exclusive or distinct from each other. Any or all elements of the embodiments of the disclosure described above may be combined with another or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An aerosol-generating device comprising:
a heater configured to heat an aerosol-generating substance;
a battery configured to supply electric power to the heater;
a memory; and
a controller configured to determine a remaining capacity of the battery during a charging state of the battery,
wherein the controller is configured to:
determine whether charging history data of charging the battery to a maximum capacity is stored in the memory;
based on the charging history data not being stored in the memory, determine a remaining capacity of the battery using an initial data table stored in the memory pertaining to at least one of charging current or charging time with respect to the charging state of the battery; and
based on the charging history data being stored in the memory, determine the remaining capacity of the battery based on the stored charging history data with respect to the charging state of the battery.

2. The aerosol-generating device according to claim 1, wherein the determination of whether the charging history data is stored in the memory is based on a voltage of the battery being greater than or equal to a predetermined voltage level, and
wherein based on the voltage of the battery being less than the predetermined voltage level, the controller is configured to determine the remaining capacity of the battery based on the voltage of the battery.

3. The aerosol-generating device according to claim 1, wherein the controller is configured to:
based on a voltage of the battery being less than a predetermined voltage level, control charging of the battery such that a current flowing through the battery is maintained at a first current level;
based on the voltage of the battery being greater than or equal to the predetermined voltage level, control charging of the battery such that the voltage of the battery is maintained at the predetermined voltage level;
calculate a time period from when the voltage of the battery becomes greater than or equal to the predetermined voltage level to when the current flowing through the battery becomes less than or equal to a second current level, wherein the second current level is lower than the first current level; and
based on the current flowing through the battery being less than or equal to the second current level and based on the charging history data not being already stored in the memory, generate and store in the memory charging history data including the calculated time period as a constant-voltage charging time.

4. The aerosol-generating device according to claim 1, wherein the initial data table includes a plurality of reference remaining capacities of the battery respectively mapped to a plurality of reference elapsed times from when a voltage of the battery reaches the predetermined voltage level during charging, and
wherein the controller is further configured to determine the remaining capacity of the battery using the initial data table stored in the memory by:
determining a reference remaining capacity from the initial data table mapped to a time elapsed since the voltage of the battery reached the predetermined voltage level.

5. The aerosol-generating device according to claim 1, wherein the charging history data includes information on a time period from when a voltage of the battery is equal to a predetermined voltage level to when the battery is charged to the maximum capacity, and
wherein the controller is further configured to determine the remaining capacity of the battery based on the charging history data by:
calculating a ratio of a time elapsed since the voltage of the battery reached the predetermined voltage level to the time period included in the charging history data, and
determining the remaining capacity being equal to a sum of an additional charged capacity corresponding to the ratio and a remaining capacity corresponding to the predetermined voltage level.

6. The aerosol-generating device according to claim 3, wherein the controller is configured to:
based on the current flowing through the battery being less than or equal to the second current level and the charging history data being already stored in the memory, compare the calculated time period with a previously stored constant-voltage charging time included in the stored charging history data;
based on the calculated time period and the previously stored constant-voltage charging time being different from each other, calculate a sum of a first value obtained by multiplying the calculated time period by a first correction coefficient and a second value obtained by multiplying the previously stored constant-voltage charging time by a second correction coefficient as a final charging time, and
update the previously stored constant-voltage charging time included in the stored charging history data with the final charging time.

7. The aerosol-generating device according to claim 6, wherein a sum of the first correction coefficient and the second correction coefficient is 1.

8. The aerosol-generating device according to claim 6, wherein the second correction coefficient is smaller than the first correction coefficient.

9. An operation method of an aerosol-generating device during a charging state of the device, the method comprising:
determining whether charging history data of charging the battery to a maximum capacity is stored in a memory of the aerosol-generating device;
based on the charging history data not being stored in the memory, determining a remaining capacity of the battery using an initial data table stored in the memory pertaining to at least one of charging current or charging time with respect to the charging state of the battery; and
based on the charging history data being stored in the memory, determining the remaining capacity of the battery based on the stored charging history data with respect to the charging state of the battery.

10. The method according to claim 9, further comprising determining, based on the voltage of the battery being less than a predetermined voltage level, the remaining capacity of the battery corresponding to the voltage of the battery based on the voltage of the battery,
wherein the determination of whether the charging history data is stored in the memory is based on a voltage of the battery being greater than or equal to the predetermined voltage level.

11. The method according to claim 9, further comprising:
based on a voltage of the battery being less than a predetermined voltage level, charging the battery such that a current flowing through the battery is maintained at a first current level;
based on the voltage of the battery being greater than or equal to the predetermined voltage level, charging the battery such that the voltage of the battery is maintained at the predetermined voltage level;
calculating a time period from when the voltage of the battery becomes greater than or equal to the predetermined voltage level to when the current flowing through the battery becomes less than or equal to a second current level, wherein the second current level is lower than the first current level; and
based on the current flowing through the battery being less than or equal to the second current level and based on the charging history data not being already stored in the memory, generating and storing in the memory charging history data including the calculated time period as a constant-voltage charging time.

12. The method according to claim 9, wherein the initial data table includes a plurality of reference remaining capacities of the battery respectively mapped to a plurality of reference elapsed times from when a voltage of the battery reaches the predetermined voltage level during charging, and
wherein the determining the remaining capacity of the battery using the initial data table stored in the memory comprises:
determining a reference remaining capacity from the initial data table mapped to a time elapsed since the voltage of the battery reached the predetermined voltage level.

13. The method according to claim 9, wherein the charging history data includes information on a time period from when a voltage of the battery is equal to a predetermined voltage level to when the battery is charged to the maximum capacity, and
wherein the determining the remaining capacity of the battery based on the charging history data comprises:
calculating a ratio of a time elapsed since the voltage of the battery reached the predetermined voltage level to the time period included in the charging history data; and
determining a sum of an additional charged capacity corresponding to the ratio and a remaining capacity corresponding to the predetermined voltage level as the remaining capacity.

14. The method according to claim 11, further comprising:
based on the current flowing through the battery being less than or equal to the second current level and the charging history data being already stored in the memory, comparing the calculated time period with a previously stored constant-voltage charging time included in the stored charging history data;
based on the calculated time period and the previously stored constant-voltage voltage charging time being different from each other, calculating a sum of a first value obtained by multiplying the calculated time period by a first correction coefficient and a second value obtained by multiplying the previously stored constant-voltage charging time by a second correction coefficient as a final charging time; and
updating the previously stored constant-voltage charging time included in the stored charging history data with the final charging time.

15. The method according to claim 14, wherein a sum of the first correction coefficient and the second correction coefficient is 1, and wherein the second correction coefficient is smaller than the first correction coefficient.
